(19) United States
(12) Patent Application Publication
(10) Pub. No.: US 2020/0349202 A1
(43) Pub. Date: Nov. 5, 2020

(54) REGULAR EXPRESSION MATCHING METHOD IN DEEP PACKET INSPECTION AND APPARATUS THEREFOR

(71) Applicant: Korea Advanced Institute of Science and Technology, Daejeon (KR)

(72) Inventors: Seungwon SHIN, Daejeon (KR); Taejune PARK, Daejeon (KR)

(21) Appl. No.: 16/684,182

(22) Filed: Nov. 14, 2019

(30) Foreign Application Priority Data
May 3, 2019 (KR) 10-2019-0051905

(51) Int. Cl. G06F 16/903; G06F 16/908; H03M 13/15

(52) U.S. Cl. CPC G06F 16/90344; G06F 9/4498; H03M 13/1575; G06F 16/908

(57) ABSTRACT

Disclosed is an regular expression matching method in deep packet inspection and an apparatus thereof. The regular expression matching method includes receiving a regular expression pattern, converting the received regular expression pattern into predetermined automata, converting the converted automata into a combination of predefined templates, and implementing the converted combination of templates as cells at a reconfigurable hardware level in real time. The converting of the received regular expression pattern into the automata includes converting the received regular expression pattern into Non-deterministic Finite Automata.

### CROSS-REFERENCE TO RELATED APPLICATIONS

A claim for priority under 35 U.S.C. § 119 is made to Korean Patent Application No. 10-2019-0051905 filed on May 3, 2019, in the Korean Intellectual Property Office, the entire contents of which are hereby incorporated by reference.

### BACKGROUND

Embodiments of the inventive concept described herein relate to a regular expression matching (REM) technology in deep packet inspection, and more particularly, relate to an regular expression matching method capable of updating regular expression pattern matching of Field-Programmable Gate Arrays (FPGA) in hardware in real time and an apparatus therefor.

Deep packet inspection (DPI) serves an important role in managing and controlling network traffic. In former times, the simple examination of a packet header has been sufficient to manage the network traffic. Nowadays, with the emergence of massive new network services, the packet payload analysis is indispensable for effectively treating such services. For example, the destination TCP port of the packet used to distribute the traffic load is identified (e.g., layer 4 load balancer). However, in general, the packet payload is inspected to efficiently manage the network services (e.g., layer 7 load balancer). The trend of packet payload inspection may be easily observed in network security services. For the purpose of detecting sophisticated network attacks, most network intrusion detection/prevention systems analyze packet payloads.

As shown in Table 1, regular expression (regex) is a meta-character with the special meaning for a character string and is useful to structure the character string including a specific pattern set (e.g., attack signature), and thus regular expression matching is one of the most important functions in DPI (e.g., IDS/IPS) for searching for an item, in which one or more specific patterns are matched in an observation character string (e.g., the packet payload in networking). However, this unfortunately causes the significant performance degradation that the regular expression matching is a major bottleneck for DPI due to the complexity of the matching process. The causes of the degradation of the regular expression matching will be briefly reviewed. Moreover, in particular, the problem of the conventional technology of enhancing performance by parallelizing a matching process focused on the approach using FPGA will be described.

TABLE 1

| Syntax | Description |
|---|---|
| • | Match any character |
| [ ] | Match a single character contained in brackets. |
| ∧ | Match the starting position in a string |
| [∧] | Match a single character not contained in brackets |
| * | Match the ending position in a string |
| + | Match the preceding element one or more times |
| ? | Match the preceding element zero or one time |
| {m,n} | Match the preceding element from m to n times |
| \| | Match either an expression before or after an operator |
| ( ) | Defines a marked subexpression |

The regular expression matching is started by generating a Finite-State Machine (FSM) equivalent to the given regular expression pattern and operating the FSM in the observation character string. Unfortunately, traversing the FSM needs to inquiry state transitions through the state graph for each input character in the observation character string, and thus it takes longer than generating the FSM and is memory-intensive. Furthermore, as the complexity and frequency of regular expression patterns increase, the regular expression matching continuously reads out the character string and needs more memory access to pass through a plurality of state graphs, thereby greatly degrading the performance.

Table 2 illustrates the change in throughput according to the different complexities and the number of regular expression patterns. It may be seen that the visible throughput decreases through simple and complex single rules as compared to a baseline (0.45˜7.65 Gbps) (e.g., the throughput decreases from 31.5% to 5.7% depending on 64 byte˜1514 byte packet size). However, as the number of regular expression patterns increases, the overall throughput is reduced drastically. The throughput according to 50 simple and complex rules indicates the average of 157.6 at 69.5 Mbps and is reduced up to maximum 97.9% or 99.1% for each case. When there are 100 rules, the throughput is not valid anymore. This throughput is mainly reduced due to frequent state transitions depending on the input character string (packet payload) and the meta-character operation and the amount of memory access increases. Moreover, as the number of rules increases, the effect of state transition overhead is accumulated. For this reason, the regular expression matching is the bottleneck of DPI, and thus the regular expression matching needs to be improved for actual deployment.

TABLE 2

| # of Rules/Type | 64B | 128B | 512B | 1024B | 1514B |
|---|---|---|---|---|---|
| No rule | 453.5 | 1280.5 | 3440.5 | 5723.0 | 7650.5 |
| 1/Simple | 344.7 | 1024.4 | 2776.2 | 5086.8 | 7236.0 |
| 1/Complex | 344.7 | 1024.4 | 2772.9 | 5089.7 | 6855.3 |
| 50/Simple | 113.4 | 128.1 | 174.8 | 195.4 | 153.4 |
| 50/Complex | 45.4 | 64.0 | 81.7 | 88.9 | 67.2 |
| 100/Simple | 56.7 | 67.4 | 75.3 | 80.9 | 49.0 |
| 100/Complex | 34.9 | 44.2 | 61.4 | 70.0 | 0.6 |

The conventional study for improving the performance of regular expression matching has been focused mainly on two parallel computing platforms (e.g., GPU) and FPGA. The GPU-based solution may process several regular expression patterns with the received packet payload, using a large number of GPU cores. However, because packet payloads may match the regular expression pattern only when being copied from the network interface to the CPU and from the CPU to the GPU, the memory transfer overhead becomes important. For this reason, the GPU-based solution reduces the overhead by collectively transmitting the received packet payload to the GPU. As a result, the total throughput may be improved, but the total latency may also increase due to batch processing. In contrast, the FPGA-based solution is directly connected to the network interface, and the state machine of the regular expression pattern is positioned at a circuit level. Accordingly, the FPGA-based solution may perform the matching process without any transfer delay. Furthermore, the FGPA hardware matches the regular expression pattern with the received packet payload within the specific time regardless of the packet length. Accordingly, the FPGA-based solution is more suitable for real-time packet inspection, and is more widely adopted in latency-sensitive networks (e.g., mission-critical networks) than the GPU-based solution.

The FPGA-based solution provides the regular expression matching of low latency. However, due to the limited flexibility of the FPGA hardware design, administrators are unfortunately reluctant to adopt the FPGA hardware design as the function of DPI in the actual network. Herein, the three important issues of the conventional solution are discussed as follows.

(1) Long compile time: Unlike the software-based solution, the FPGA-based solution requires a compile process (i.e., synthesis, map, deployment, and routing) to update the regular expression pattern at the circuit level. However, it takes at least a couple of hours to perform this process. Furthermore, in the worst case, it takes two days to perform this process. This means that it is difficult to immediately apply a specific regular expression pattern to the FPGA hardware.

(2) Inevitable service interruption: after the compile process, the FPGA-based solution may not avoid the service interruption due to the FPGA hardware initialization of the updated regular expression pattern. This may take less time than the compiling process (from a few seconds to 30 seconds). However, in terms of the possibility of a service, because the network is temporarily exposed to potential threats during initialization, the administrators may have an operational burden.

(3) All-or-Nothing update function: Currently FGPA-based solutions do not allow partial updates of circuits, so regular expression pattern needs to be updated in an all-or-nothing scheme. Accordingly, the whole compile process and the initialization of the FPGA hardware is needed even when the regular expression pattern is small changed. For this reason, the update of the regular expression pattern may be burdened to administrators. Accordingly, they need to update the regular expression pattern at regular intervals (storing updates and applying updates at a time) instead of actively applying the updates.

### SUMMARY

Embodiments of the inventive concept provide a regular expression matching method capable of updating regular expression pattern matching of FPGA in hardware in real time and an apparatus therefor.

Embodiments of the inventive concept provide a regular expression matching method capable of updating regular expression pattern matching of FPGA in real time by implementing the regular expression pattern matching of FPGA at a logic level and an apparatus therefor.

According to an exemplary embodiment, a regular expression matching method includes receiving a regular expression pattern, converting the received regular expression pattern into predetermined automata, converting the converted automata into a combination of predefined templates, and implementing the converted combination of templates as cells at a reconfigurable hardware level in real time.

The converting of the received regular expression pattern into the automata includes converting the received regular expression pattern into Non-deterministic Finite Automata.

The converting of the converted automata into the combination of the templates includes converting the converted automata into a logic template of a cell combination at the reconfigurable hardware level, and the implementing includes implementing the converted logic template as cells at the hardware level in real time.

The converting of the received regular expression pattern into the automata includes dividing the received regular expression pattern into subexpressions and converting the divided subexpressions into the automata. The converting of the converted automata into the combination of templates includes converting each of the subexpressions into a logic template of a cell combination at the reconfigurable hardware level, based on the converted automata. The implementing includes implementing the converted logical template as cells at the hardware level in real time, with respect to each of the subexpressions.

The implementing includes implementing the combination of templates corresponding to the received regular expression pattern as cells at the reconfigurable hardware level in real time by detecting cells to be updated through comparison between a first regular expression pattern implemented as the cells at the reconfigurable hardware level and the received regular expression pattern to update the detected cells.

The implementing includes expressing the first regular expression pattern and the received regular expression pattern as a meta-character list, constructing an area in which two meta-character lists overlap with each other as two pieces of lists, and detecting remaining cells as cells to be updated, by calculating Hamming distance between the two pieces of lists to preserve cells corresponding to a meta-character for an overlapping area of a smallest Hamming distance.

According to an exemplary embodiment, an regular expression matching apparatus includes a reception unit receiving a regular expression pattern, a conversion unit converting the received regular expression pattern into predetermined automata and converting the converted automata into a combination of predefined templates, and an implementation unit implementing the converted combination of templates as cells at a reconfigurable hardware level in real time.

The conversion unit converts the received regular expression pattern into Non-deterministic Finite Automata.

The conversion unit converts the converted automata into a logic template of a cell combination at the reconfigurable hardware level, and the implementation unit implements the converted logic template as cells at the hardware level in real time.

The conversion unit divides the received regular expression pattern into subexpressions, converts the divided subexpressions into the automata, and converts each of the subexpressions into a logic template of a cell combination at the reconfigurable hardware level, based on the converted automata, and the implementation unit implements the converted logical template as cells at the hardware level in real time, with respect to each of the subexpressions.

The implementation unit implements the combination of templates corresponding to the received regular expression pattern as cells at the reconfigurable hardware level in real time by detecting cells to be updated through comparison between a first regular expression pattern implemented as the cells at the reconfigurable hardware level and the received regular expression pattern to update the detected cells.

The implementation unit expresses the first regular expression pattern and the received regular expression pattern as a meta-character list, constructs an area in which two meta-character lists overlap with each other as two pieces of lists, and detects remaining cells as cells to be updated, by calculating Hamming distance between the two pieces of lists to preserve cells corresponding to a meta-character for an overlapping area of a smallest Hamming distance.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates an operation flowchart of a regular expression matching method, according to an embodiment of the inventive concept;

FIG. 2 illustrates the hardware architecture of Reinhardt and an operation flowchart, according to an embodiment of the inventive concept;

FIG. 3 illustrates one exemplary view of a Reinhardt core;

FIG. 4 illustrates one exemplary view for describing a process of deploying a regular expression pattern in a Reinhardt core;

FIG. 5 illustrates one exemplary view for describing a case of revising or deleting the pattern deployed in a Reinhardt core;

FIG. 6 illustrates one exemplary view for describing a process of a resubmitting function; and

FIG. 7 illustrates a conceptual configuration of a regular expression matching apparatus, according to an embodiment of the inventive concept.

### DETAILED DESCRIPTION

Advantage points and features of the inventive concept and a method of accomplishing thereof will become apparent from the following description with reference to the following figures, wherein embodiments will be described in detail with reference to the accompanying drawings. The inventive concept, however, may be embodied in various different forms, and should not be construed as being limited only to the illustrated embodiments. Rather, these embodiments are provided as examples so that the inventive concept will be thorough and complete, and will fully convey the concept of the inventive concept to those skilled in the art. The inventive concept may be defined by scope of the claims. Meanwhile, the terminology used herein to describe embodiments of the invention is not intended to limit the scope of the invention.

The terminology used herein is for the purpose of describing embodiments and is not intended to limit the inventive concept. In the specification, the singular forms include plural forms unless particularly mentioned. The terms “comprises” and/or “comprising” used herein does not exclude presence or addition of one or more other components, steps, operations, and/or elements in addition to the aforementioned components, steps, operations, and/or elements.

Unless otherwise defined, all terms (including technical and scientific terms) used herein have the same meaning as commonly understood by those skilled in the art to which the inventive concept pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

Hereinafter, exemplary embodiments of the inventive concept will be described in detail with reference to the accompanying drawings. The same reference numerals are used for the same components in the drawings and redundant explanations for the same components are omitted.

The regular expression matching is an important part of deep packet inspection (DPI). However, the low performance of regular expression matching becomes the bottleneck in DPI. For the purpose of accelerating the regular expression matching, the FPGA-based study has used parallel processing by simultaneously matching several regular expression patterns. However, while ensuring high throughput and low latency, the conventional FPGA-based regular expression matching may not support the dynamic update during runtime. As a result, it is not suitable for the DPI function in which a malicious signature is changed frequently.

Embodiments of the inventive concept are directed to update the regular expression pattern in real time by implementing the regular expression pattern matching of FPGA at a logic level.

Herein, the inventive concept may provide a new hardware architecture called “Reinhardt”, which is a real-time reconfigurable hardware architecture for regular expression matching, and may switch the paradigm of FPGA regular expression pattern matching from the circuit level to the logic level.

At this time, Reinhardt may be configured as a reconfigurable cell capable of changing the real-time connection, and may directly implement regular expression patterns as the state machine logic in hardware by combining cells. The inventive concept makes it possible to fast and dynamically deploy and revise regular expression patterns without compile time and service interruption.

Furthermore, the inventive concept may convert the subexpression of the target regular expression pattern into the logic template of the reconfigurable cell combination optimized to implement a state machine; the inventive concept may automatically search for the traffic through another regular expression pattern set depending on a network policy or a security level because another regular expression pattern from a memory is dynamically fetched under the predefined condition.

At this time, the inventive concept may convert the regular expression pattern into Non-deterministic Finite Automata (NFA) and then may convert NFA into the logic template of the reconfigurable cell combination.

Furthermore, the inventive concept may perform a function to resubmit for the purpose of implementing real-time update function and may increase the number of available regular expression patterns ‘n’ times by slightly reducing the latency while preserving throughput.

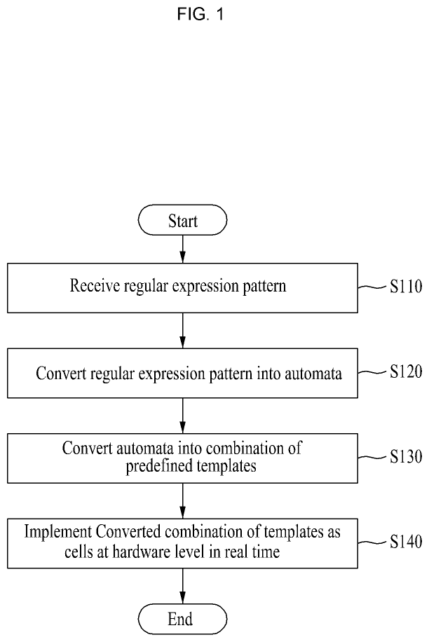

FIG. 1 illustrates an operation flowchart of a regular expression matching method, according to an embodiment of the inventive concept.

Referring to FIG. 1, the regular expression matching method according to an embodiment of the inventive concept receives the regular expression pattern to be implemented through Reinhardt in operation S110 and then converts the received regular expression pattern into automata in operation S120.

Herein, operation S120 may convert the regular expression pattern into NFA; in operation S120, the relationship between partial character strings of the regular expression pattern may be understood via automata.

When the regular expression pattern is converted into automata (e.g., NFA) in operation S120, in operation S130, the regular expression matching method converts and generates the converted automata as the combination of the predefined templates.

Herein, operation S130 may convert the subexpression of the regular expression pattern into the logic template of the reconfigurable cell combination optimized to implement the state machine.

When the subexpression of the regular expression pattern is converted into the combination of templates in operation S130, in operation S140, the regular expression matching method implements the converted combination of templates as cells at a hardware level in real time.

That is, operation S140 may implement the regular expression pattern at a hardware level in real time by implementing the converted combination of templates as logic cells constituting a Reinhardt core in real time.

As such, the inventive concept makes it possible to fast and dynamically deploy and revise regular expression patterns without compile time and service interruption, because the inventive concept implements the regular expression pattern through reconfigurable cells in real time.

The inventive concept may be associated with the highly reconfigurable FPGA-based regular expression matching and may have two folds. First, the new and updated regular expression pattern needs to be dynamically applied after the editing process is minimized as much as possible. Second, there is a need to selectively update the regular expression pattern of FPGA hardware without service interruption. In consideration of these details, the inventive concept proposes the FPGA architecture called “Reinhardt” that newly redesigns the reconfigurable FPGA block as reconfigurable cells. Next, Reinhardt directly converts the given regular expression pattern, which is represented as NFA, into Reinhardt's reconfigurable cell configuration, thereby greatly reducing compile time. In the latter case, Reinhardt provides an API such that an administrator may dynamically update the specific regular expression pattern and selectively revises the reconfigurable cell for the target regular expression pattern without service interruption.

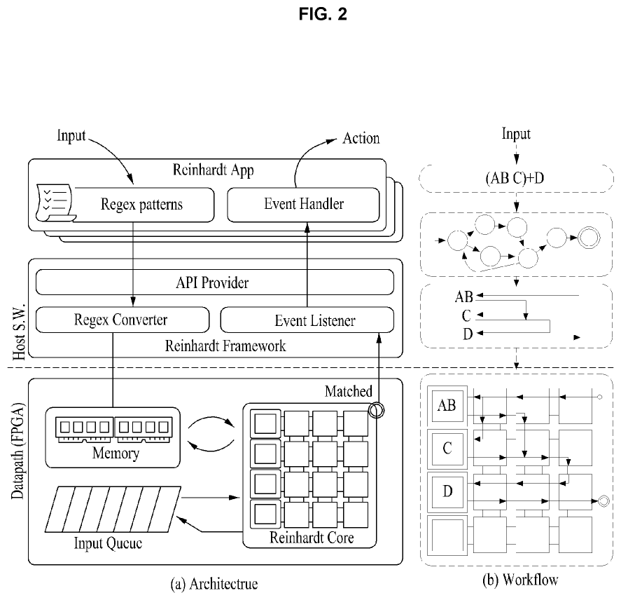

The method of dynamically generating and utilizing the state machine by using Reinhardt, which is a real-time reconfigurable architecture for the regular expression matching according to an embodiment of the inventive concept and FPGA hardware will be described with reference to FIGS. 2 to 6 as follows.

Whole Design

FIG. 2 illustrates the hardware architecture of Reinhardt and an operation flowchart, according to an embodiment of the inventive concept.

As shown in FIG. 2, the Reinhardt includes a Reinhardt core processing an observation character string and positioned in a datapath (FPGA), a memory and an input queue, a regular expression converter and an event listener positioned in a host software framework controlling a Reinhardt datapath. The software framework provides an API that transmits the regular expression pattern to the datapath by the implementation of a Reinhardt application or registers the event handler in a listener to receive a message in the datapath. The Reinhardt core consists of a set of reconfigurable cells connected to a ‘w×h’ grid topology with input/output ports for each direction (i.e., Top-Bottom-Left-Right). Each cell may dynamically determine the output direction of the input signal, depending on the host software configuration.

The greatest advantage of Reinhardt is that Reinhardt may update the regular expression pattern in hardware in real time without service interruption. The update includes all actions associated with the management of the regular expression pattern such as 1) new pattern deployment and 2) revising/removing a part of patterns previously deployed. The key idea of Reinhardt is that the target regular expression pattern is expressed directly as the NFA of the Reinhardt core via the combination of cell connections. As illustrated in FIG. 2B, when the regular expression is given, the corresponding NFA architecture is expressed as the combination reconfigurable cells by the regular expression converter. Because the conversion result is stored in a memory to change the input/output direction of a cell in a core, the equivalent state machine for the regular expression pattern is implemented in real time. The design of Reinhardt may support all common meta-characters as described in Table 1. The observation character string is inspected by operating NFA logic in the core; when a pattern, which is matched in the Reinhardt core, is discovered, a notification is transmitted to the event listener of a host. Next, the event listener provides a notification of an application using the event handler and takes an action depending on the matched result, such as updating a list of regular expression patterns or the like, to block suspicious traffic or to enhance inspection, for example.

Reinhardt Core

For the purpose of understanding a method of implementing the NFA in FPGA. First, the architecture of the Reinhardt core will be described as follows.

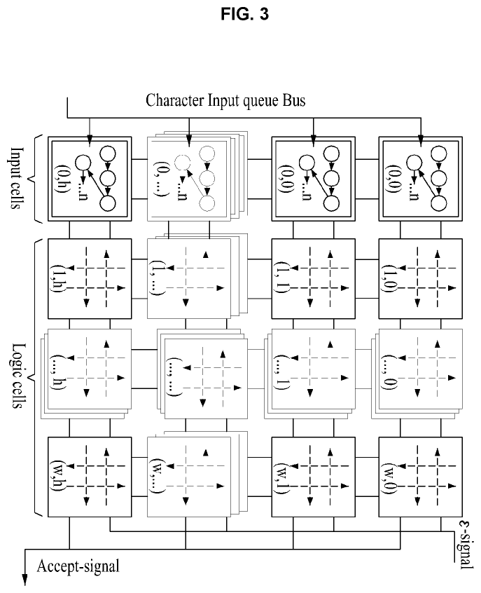

FIG. 3 illustrates one exemplary view of a Reinhardt core, and illustrates one exemplary view of ‘w×h’ Reinhardt cores

As illustrated in FIG. 3, the Reinhardt core may be composed of two types of reconfigurable cells (e.g., an input cell and a logic cell); the 0-th column of a grid may be composed of the input cell and the remaining cells of the grid may be composed of the logic cells. Each cell is connected to a neighboring cell by the input/output port in the top-bottom-left-right direction; the location of each cell is expressed as coordinates (x, y). The character input queue bus is connected to the input cell positioned at the left of the core; a ε-signal bus and an accept-signal bus are connected to the logic cells positioned at the right of the core.

For the purpose of performing regular expression pattern matching, the given regular expression pattern is converted into the NFA by the core by combining the above-described cells. The pattern is divided into a sub character string and a meta-character; the sub character string is deployed in the input cell; the relationship (i.e., the operation by the meta-character) thereof is expressed as each connection of the logic cell. For clarity, the regular expression pattern of ‘abc|xyz’ is separated into ‘abc’ and ‘xyz’; afterward, the meta-character may be expressed as the connection of a logic cell.

Input cell: The input cell indicates a state and is activated and converted via an input/output port connected to the logic cell positioned at the right side of the input cell. The input cell is in an automata state of a linear chain of length ‘m’ and operates as a simple ‘m’ character string matcher. When the state is activated, the input cell starts to be compared with the observation character; when all characters are matched, a state transition is performed to the output port. The input cell may not only function as a simple character string matcher but also compare the observation character to the min-max range. For example, when the character (i.e., bracket expression [a-f]) between ‘a’ and ‘f’ is found, the target minimum character is set to ‘a’ and the target maximum character is set to ‘f’. Moreover, the input cell may take a flag for the observation character to display the start and end of the character string or may display the condition (e.g., \hat{ }, $, and [\hat{ }]) that the start and end of the character string are not included.

Logic cell: The logic cell operates as directed edges that connect the state in the state machine. The directed edges function by manipulating an internal gate/switch to forward the input signal (i.e., the state transition) from each direction to the specified direction. As well as the switching characteristics, the logic cell includes a counter capable of counting the number of times that a state transition occurs in the region. In this way, the logic cell may implement a state where the condition needs to be satisfied the specific number of times, and is useful to express the interval operator {m, n}.

Core I/O: The input of the Reinhardt core consists of the character input bus and the ε-signal. The character input bus broadcasts the observation character string to the input cell. The ε-signal indicates the start of NFA by triggering an initial state (i.e., the input cell for the first character of a given regular expression pattern) via the logic cell. The output of the Reinhardt core is an accept-signal. The accept-signal provides a notification of the end of the NFA by triggering the final state (i.e., the input cell for the last sub character string). This signal is transmitted when the observation character string is matched to the given regular expression pattern.

Convert Regular Expression to Reinhardt Cell Logic

The inventive concept may convert the regular expression pattern to NFA depending on Thompson's configuration algorithm. The given regular expression pattern is divided into subexpressions (e.g., literal characters and meta-characters) in this algorithm. This subexpression may be expressed as the basic NFA architecture and may be used as a building block. The whole NFA may be implemented by synthesizing this partial NFA architecture. Naturally, the inventive concept does not limit converting the regular expression pattern into NFA using only Thompson' s construction algorithm; it is obvious to those skilled in the art that all types of algorithms capable of converting the regular expression pattern into NFA may be used.

For the purpose of implementing NFA in the Reinhardt core, Reinhardt software allows the cell configuration to configure NFA logic in the manner similar to this algorithm. The subexpression is classified into the sub character string and the meta-character; each subexpression may be implemented with the template indicating a partial NFA architecture by the combination of cells described in Table 3. When the input/output port of the template is connected, the larger NFA logic is repeatedly formed in the core.

TABLE 3

| Regex sample | NFA Snippet | Reinhardt logic template |
|---|---|---|
| . | [symbol] | [symbol] |
| | | (Match from null) |
| [0-9] | [symbol] | [symbol] |
| | | (Match to min/max range) |
| \hat{ }A | [symbol] | [symbol] |
| | | (With ‘begin’ flag) |
| [\hat{ }a-z] | [symbol] | [symbol] |
| | | (With ‘not’ flag) |
| A$ | [symbol] | [symbol] |
| | | (With ‘last’ flag) |
| A* | [symbol] | [symbol] |
| A+ | [symbol] | [symbol] |
| A? | [symbol] | [symbol] |
| A{m, n} | [symbol] | [symbol] |
| (A{m}, A{m,}) | | (Through a counter range) |
| A\|B | [symbol] | [symbol] |
| (AB)(CD) | [symbol] | [symbol] |

Algorithm 1 below describes this operation. First, algorithm 1 takes the number of starting rows to deploy the NFA generated in the core and the target regular expression pattern and initializes the stack that stores the input/output coordinates and the direction (i.e., Top-Bottom-Left-Right) for the partial NFA last generated until now. Next, the given regular expression pattern is converted in the form of postfix to reflect the precedence in which the partial NFA is generated, and is interpreted by sequentially reading out the postfix. 1) The sub character string is deployed in the input cell of each row; whenever one sub character string input is completed, the sub character string is considered as the single small NFA in which the input/output coordinates of the input cell are stored in the stack. Herein, the input/output of the input cell is always positioned at the right, and thus the direction is fixed to ‘R’. 2) In the meta-character, algorithm 1 reads out the coordinates of the most recently generated partial NFA from the stack by the required number of operands and synthesizes the operand NFA as the larger NFA, using the meta-character template. Next, the input/output coordinates of the larger NFA are stored as the new partial NFA. This operation is performed recursively, and thus the whole NFA is completed by connecting the ε-signal and the accept-signal to the last stacked NFA.

This conversion result is immediately transmitted and stored in the memory of hardware, and the Reinhardt core controls each of the cells to reflect the configuration.

Algorithm 1: Regex Pattern to Reinhardt Cell Logic

Input: start_row, Start row in the Reinhardt core
Input: regex, Given regex pattern
row ← start_row
STACK ( in[x,y,d], out[x′,y′,d′] ) // Stack for IN/OUT
// x,y,d: cell coordinates with its direction
postfix ← Regex_to_postfix (regex)
foreach Character c in postfix do

| \| | switch c do | | | |
|---|---|---|---|---|
| \| | \| | case ‘Literal’ | | |
| \| | \| | \| | setInput (row, c) | |
| \| | \| | \| | if c is End of Substring then | |
| \| | \| | \| | \| | PUSH ( [0,row,‘R’], [0, row, ‘R’] ) |

| | | | | |
|---|---|---|---|---|
| \| | \| | \| | \|_ | row ← row +1 |

| \| | \| | \|_{—} | |
|---|---|---|---|
| \| | \| | case ‘Unary_metachar’ | |
| \| | \| | \| | [in1, out1] ← POP ( ) |
| \| | \| | \| | [in′, out′] ← setTemplate ( c, [in1, out1]) |

| | | | |
|---|---|---|---|
| \| | \| | \|_ | PUSH ([in′, out′]) |

| \| | \| | case ‘Binary_metachar’ | |
|---|---|---|---|
| \| | \| | \| | [in2, out2] ← POP ( ) |
| \| | \| | \| | [in1, out1] ← POP ( ) |
| \| | \| | \| | [in′, out′] ← setTemplate ( c, [in1, out1], [in2, out2]) |

| | | | |
|---|---|---|---|
| \| | \| | \|_ | PUSH ( [in′ out′]) |

| | |
|---|---|
| \| | \|_{—} |

|_{—}
[in1, out1] ← POP( )
setESignal (in1)
setAcceptSignal (out1)

Pattern Update Breakdown

In the inventive concept, the detailed process of the update operation for distributing a new pattern and for revising and deleting the already distributed pattern will be described.

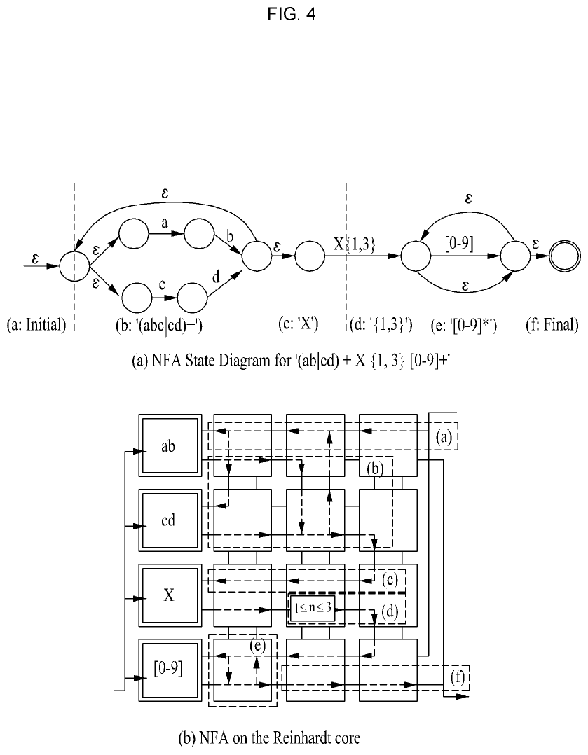

Regular expression pattern deployment: FIG. 4 illustrates one exemplary view for describing the process of deploying a regular expression pattern in a Reinhardt core; FIG. 4 illustrates one exemplary view for describing the process of deploying a regular expression pattern ‘(ab|cd)+X{1,3}[0-9]*’ in 4×4 Reinhardt cores.

When the state diagram of the regular expression pattern ‘(ab|cd)+X{1,3}[0-9]*’ illustrated in FIG. 4 (a) is compared with NFA on the Reinhardt core illustrated in FIG. 4 (b), the edges of the state diagram are expressed as logic cells of the same shape, and the characters tied using a chain in a linear line are represented by input cells. This means that each subexpression is mapped one to one, and thus the equivalent state machine is implemented. The state of the observation character string is switched via each section starting from (a) ε-signal of FIG. 4B to (f); the accept-signal indicates that the observation character string is matched to the regular expression pattern and is received.

Herein, an embodiment is exemplified in FIG. 4 as the size of a Reinhardt core is 4×4 Reinhardt cores having a single regular expression pattern, but this is only for convenience of description. In the inventive concept, the size of the Reinhardt core may be changed. That is, due to the transformation of the larger and more patterns, the size of an actual core may represent more complex patterns. In general, as the width ‘w’ of the core increases, more meta-characters may be represented, that is, more complex regular expression patterns may be represented; as the height ‘h’ of the core increases, more regular expression patterns may be represented and may be matched at the same time. The size of the core is closely associated with the use of FPGA resources.

Revising/deleting deployment pattern: After deploying a regular expression pattern, Reinhardt allows the original pattern to be revised concisely. Reinhardt matches the meta-character of the original pattern, with the revised pattern, and determines which logic cell circuits needs to be preserved or rewired. This determination is made by 1) expressing two regular expression patterns as meta-character lists. 2) after two lists overlap with the random number of meta-characters, the overlapping area overlap to constitute fragments of two lists. 3) Hamming distance between fragments of two lists may be calculated. 4) The above steps are repeated by overlapping with two lists with different overlapping sizes or locations. The matching meta-character in the overlapping area of the smallest Hamming distance between the fragments of the two lists is the logic cell that needs to be preserved when the regular expression pattern is revised.

The inventive concept may reuse the part of the circuit in the original regular expression pattern by detecting which part of the logic cell needs to be revised as compared with the case where the whole circuit is revised, thereby reducing the overhead for revision.

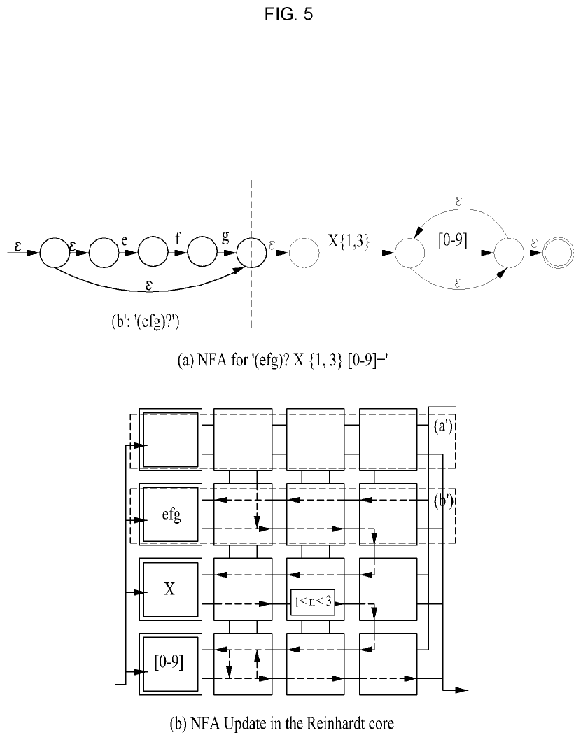

FIG. 5 illustrates one exemplary view for describing the case of revising or deleting the pattern deployed in a Reinhardt core; FIG. 5 illustrates one exemplary view of the case that NFA of FIG. 4 (a) is revised as NFA of FIG. 5 (a).

As illustrated in FIG. 5, it is illustrated how Reinhardt detects the fragment of a list having the smallest Hamming distance between (ab|cd)+X{1,3} [0-9]*′ and ‘(efg)?X{1,3}[0-9]*’; it is understood that the logic cell starting from the second column, that is, (b′) is maintained during the revision as it is. Furthermore, in the case of (a′), it is understood how the revision is capable of being recognized by removing the part of the deployed regular expression pattern; the basis for efficient revision may also be applied to the removal.

There is a need to note that the fragmentation similar to the fact that repeated deployment and deletion (or removal) of patterns of different lengths occurs in memory management may occur. For this reason, the cell may be inefficiently utilized even though the sufficient space is ensured in the whole Reinhardt core, or it may be difficult to deploy a new pattern. Accordingly, for the purpose of efficiently use the Reinhardt, the Reinhardt may utilize the conventional memory management algorithm such as compaction or garbage collection.

Reinhardt Memory and Input Queue

The remaining components of a Reinhardt datapath are a memory and an input queue. Both the memory and the input queue help the Reinhardt core to match the observation character string with the better performance.

NFA memory fetching: a Reinhardt memory may store multiple cell configurations, and the core may dynamically fetch NFA logic under the predefined condition. The Reinhardt core interchangeably provides a regular expression pattern for detecting SQL injection for HTTP traffic and a regular expression pattern for detecting malware for the FTP protocol, and thus it is indicated that the additional protocol inspection function is added to the input queue.

Multiple packets-driving queue: For the purpose of matching the observation character string, each character is sequentially entered into the Reinhardt when the character string is entered into the input queue. This operation is an essential procedure to operating a finite state machine. However, the next observation character string is delayed by the length of the observation character string currently being processed by the Reinhardt. This becomes an important barrier and bottleneck in reducing the throughput of pattern matching. To solve this problem, the inventive concept designs an input queue as ‘n’ multiple packet driving queues.

The single observation character string is present in each packet driving queue, and the observation character string arriving at the input queue is distributed between several queues in the arrival order. Also, each character of the queue is entered to the Reinhardt core at the same time without waiting until the observation character string is finished. For the purpose of processing different states of each observation character string in multiple queues, the core is also composed of multiple layers, and is matched each queue one to one.

The number ‘n’ of packet driving queues may determine the throughput of the Reinhardt. However, as the number of queues increases, the number of core layers increases. Therefore, there is a need for a lot of FPGA resources. Accordingly, it is important to search for the optimal number of queues, and the number of packet driving queues may be determined based on the throughput of the Reinhardt and the FPGA resources.

Resubmitting: the performance of the Reinhardt may increase by combining two functions of the NFA memory fetching and multiple packets-driving queues. The main advantage of the Reinhardt is that it is possible to update the regular expression pattern in real time; the Reinhardt matches the observation character string with several regular expression patterns and multiplies the number of Reinhardt cores. ID is allocated to each regular expression pattern set to a memory; this set includes the regular expression pattern list to which a packet queue is matched.

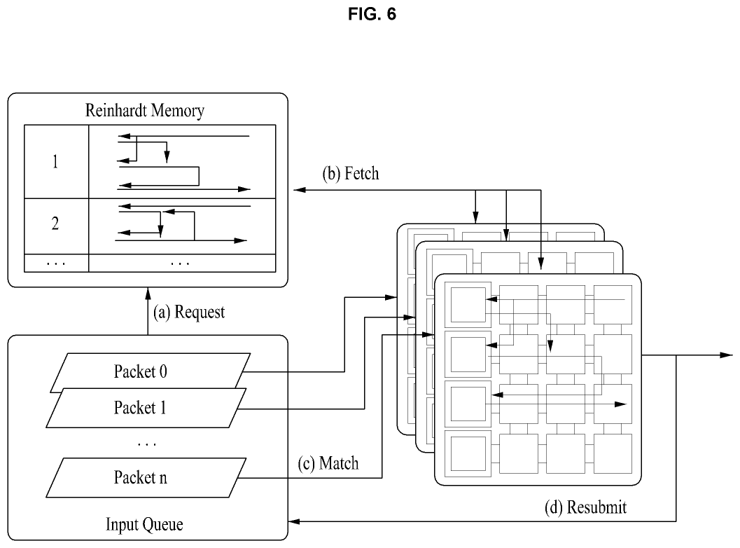

FIG. 6 illustrates one exemplary view for describing a process of a resubmitting function. As illustrated in FIG. 6, operation (a) (request) includes a process of making a request for a pattern ID set for a match. In operation (b) (fetch), the pattern of the set is fetched and then is deployed in a Reinhardt core; operation (c) (match) illustrates the actual match of the observation character string. In final operation (d) (resubmit), the observation character string is resubmitted to the input queue with respect to the next pattern of the set ID, and this process is repeated. The resubmitting enables much more regular expression patterns to be matched despite the size of the core; the method of an additional inspection policy is set depending on the security level of traffic.

Detecting Processing

When the matched pattern is found, that is, when the state transition of NFA is reached to an accept-signal, the Reinhardt core sends a notification message to an event listener. This message includes the row number of the Reinhardt core indicating which pattern is matched. The received notification is transmitted to an application of registering a Reinhardt event handler in the event listener; the follow-up measures of the received matching result may be taken. For example, the event handler may build an automatic security system that warns administrators, updates signatures, or blocks malicious IP addresses.

As such, a method according to an embodiment of the inventive concept may update the regular expression pattern in real time by implementing regular expression pattern matching of FPGA at a logic level and may convert the paradigm of the regular expression pattern matching of FPGA from a circuit level to a logic level.

Furthermore, the method according to an embodiment of the inventive concept may make it possible to fast and dynamically deploy and revise regular expression patterns without compile time and service interruption.

Also, the method according to an embodiment of the inventive concept may convert the subexpression of the target regular expression pattern into the logic template of the reconfigurable cell combination optimized to implement a state machine, and may automatically search for the traffic through another regular expression pattern set depending on a network policy or a security level because dynamically fetching another regular expression pattern from a memory under the predefined condition.

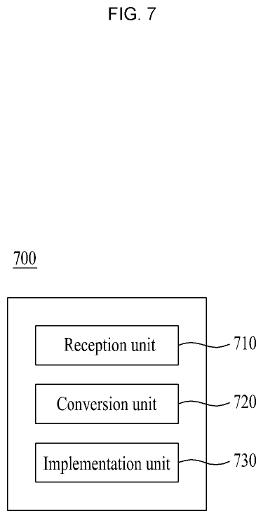

FIG. 7 illustrates a conceptual configuration of a regular expression matching apparatus, according to an embodiment of the inventive concept; FIG. 7 illustrates a conceptual configuration of an apparatus performing the method of FIGS. 1 to 6.

Referring to FIG. 7, an apparatus 700 according to an embodiment of the inventive concept includes a reception unit 710, a conversion unit 720, and an implementation unit 730.

The reception unit 710 receives a regular expression pattern to be implemented or deployed.

The conversion unit 720 converts the received regular expression pattern into the predetermined automata and converts the converted automata into the combination of predefined templates.

Herein, the conversion unit 720 may convert the received regular expression pattern into NFA.

Furthermore, the conversion unit 720 may convert the converted automata into the logic template of the cell combination at the reconfigurable hardware level. In particular, the conversion unit 720 may divide the received regular expression pattern into subexpressions, may convert the divided subexpressions into NFA, and may convert each of the subexpressions into a logic template of a cell combination at the reconfigurable hardware level based on the converted NFA.

The implementation unit 730 implements the converted combination of templates as cells at a reconfigurable hardware level in real time. That is, the implementation unit 730 implements the regular expression pattern in a logic cell constituting the Reinhardt core in real time.

At this time, the implementation unit 730 may implement the converted logic template as cells at a hardware level in real time; when each of the subexpressions is converted into the logic template of the cell combination at the reconfigurable hardware level by the conversion unit 720, the implementation unit 730 may implement the converted logic template as cells at the hardware level in real time with respect to each of the subexpressions.

Furthermore, the implementation unit 730 may implement the combination of templates corresponding to the received regular expression pattern as cells at the reconfigurable hardware level in real time by detecting cells to be updated through comparison between a first regular expression pattern and the received regular expression pattern from cells at the reconfigurable hardware level to update the detected cells.

At this time, the implementation unit 730 may express the first regular expression pattern and the received regular expression pattern as a meta-character list, may construct an area in which two meta-character lists overlap with each other as fragments of two lists, and may detect the remaining cells as cells to be updated, by calculating Hamming distance between the two pieces of lists to preserve cells corresponding to a meta-character for an overlapping area of the smallest Hamming distance.

Even though the description is omitted in the apparatus in FIG. 7, it will be apparent to those skilled in the art that the apparatus in FIG. 7 may include all content described in FIGS. 1 to 6.

The above-described system or device may be implemented with hardware elements, software elements, and/or a combination of hardware elements and software elements. For example, the systems, the devices and components described in the exemplary embodiments of the inventive concept may be implemented in one or more general-use computers or special-purpose computers, such as a processor, a controller, an arithmetic logic unit (ALU), a digital signal processor, a microcomputer, a field programmable array (FPA), a programmable logic unit (PLU), a microprocessor or any device which may execute instructions and respond. A processing unit may perform an operating system (OS) or one or software applications running on the OS. Further, the processing unit may access, store, manipulate, process and generate data in response to execution of software. It will be understood by those skilled in the art that although a single processing unit may be illustrated for convenience of understanding, the processing unit may include a plurality of processing elements and/or a plurality of types of processing elements. For example, the processing unit may include a plurality of processors or one processor and one controller. Also, the processing unit may have a different processing configuration, such as a parallel processor.

Software may include computer programs, codes, instructions or one or more combinations thereof and configure a processing unit to operate in a desired manner or independently or collectively control the processing unit. Software and/or data may be permanently or temporarily embodied in any type of machine, components, physical equipment, virtual equipment, computer storage media or units or transmitted signal waves so as to be interpreted by the processing unit or to provide instructions or data to the processing unit. Software may be dispersed throughout computer systems connected via networks and be stored or executed in a dispersion manner. Software and data may be recorded in one or more computer-readable storage media.

While a few exemplary embodiments have been shown and described with reference to the accompanying drawings, it will be apparent to those skilled in the art that various modifications and variations can be made from the foregoing descriptions. For example, adequate effects may be achieved even if the foregoing processes and methods are carried out in different order than described above, and/or the aforementioned elements, such as systems, structures, devices, or circuits, are combined or coupled in different forms and modes than as described above or be substituted or switched with other components or equivalents.

Therefore, other implements, other embodiments, and equivalents to claims are within the scope of the following claims.

According to embodiments of the inventive concept, it is possible to update the regular expression pattern matching of FPGA in hardware in real time. The inventive concept may update the regular expression pattern in real time by implementing the regular expression pattern matching of FPGA at the logic level

According to embodiments of the inventive concept, the compile time may be shortened by directly implementing the reconfigurable cell configuration of Reinhardt after the regular expression pattern is converted into Non-deterministic Finite Automata (NFA); an administrator may provide an API to dynamically update the specific regular expression pattern and may selectively revise the reconfigurable cell for the target regular expression pattern without service interruption.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A regular expression matching method, the method comprising:
receiving a regular expression pattern;
converting the received regular expression pattern into predetermined automata;
converting the converted automata into a combination of predefined templates; and
implementing the converted combination of templates as cells at a reconfigurable hardware level in real time.

2. The method of claim 1, wherein the converting of the received regular expression pattern into the automata includes:
converting the received regular expression pattern into Non-deterministic Finite Automata.

3. The method of claim 1, wherein the converting of the converted automata into the combination of the templates includes:
converting the converted automata into a logic template of a cell combination at the reconfigurable hardware level, and
wherein the implementing includes:
implementing the converted logic template as cells at the hardware level in real time.

4. The method of claim 1, wherein the converting of the received regular expression pattern into the automata includes:
dividing the received regular expression pattern into subexpressions; and
converting the divided subexpressions into the automata,
wherein the converting of the converted automata into the combination of templates includes:
converting each of the subexpressions into a logic template of a cell combination at the reconfigurable hardware level, based on the converted automata, and
wherein the implementing includes:
implementing the converted logical template as cells at the hardware level in real time, with respect to each of the subexpressions.

5. The method of claim 1, wherein the implementing includes:
implementing the combination of templates corresponding to the received regular expression pattern as cells at the reconfigurable hardware level in real time by detecting cells to be updated through comparison between a first regular expression pattern implemented as the cells at the reconfigurable hardware level and the received regular expression pattern to update the detected cells.

6. The method of claim 5, wherein the implementing includes:
expressing the first regular expression pattern and the received regular expression pattern as a meta-character list;
constructing an area in which two meta-character lists overlap with each other as two pieces of lists; and
detecting remaining cells as cells to be updated, by calculating Hamming distance between the two pieces of lists to preserve cells corresponding to a meta-character for an overlapping area of a smallest Hamming distance.

7. An regular expression matching apparatus, the apparatus comprising:
a reception unit configured to receive a regular expression pattern;
a conversion unit configured to convert the received regular expression pattern into predetermined automata and configured to convert the converted automata into a combination of predefined templates; and
an implementation unit configured to implement the converted combination of templates as cells at a reconfigurable hardware level in real time.

8. The apparatus of claim 7, wherein the conversion unit converts the received regular expression pattern into Non-deterministic Finite Automata.

9. The apparatus of claim 7, wherein the conversion unit converts the converted automata into a logic template of a cell combination at the reconfigurable hardware level, and
wherein the implementation unit implements the converted logic template as cells at the hardware level in real time.

10. The apparatus of claim 7, wherein the conversion unit divides the received regular expression pattern into subexpressions, converts the divided subexpressions into the automata, and converts each of the subexpressions into a logic template of a cell combination at the reconfigurable hardware level, based on the converted automata, and
wherein the implementation unit implements the converted logical template as cells at the hardware level in real time, with respect to each of the subexpressions.

11. The apparatus of claim 7, wherein the implementation unit implements the combination of templates corresponding to the received regular expression pattern as cells at the reconfigurable hardware level in real time by detecting cells to be updated through comparison between a first regular expression pattern implemented as the cells at the reconfigurable hardware level and the received regular expression pattern to update the detected cells.

12. The apparatus of claim 11, wherein the implementation unit expresses the first regular expression pattern and the received regular expression pattern as a meta-character list, constructs an area in which two meta-character lists overlap with each other as two pieces of lists, and detects remaining cells as cells to be updated, by calculating Hamming distance between the two pieces of lists to preserve cells corresponding to a meta-character for an overlapping area of a smallest Hamming distance.
